(19) United States
(12) Patent Application Publication
(10) Pub. No.: US 2017/0321020 A1
(43) Pub. Date: Nov. 9, 2017

(54) COMPOSITE STRUCTURE COMPRISING A RESIN LOADED WITH FLAT GRAPHENE SHEETS HAVING ENHANCED THERMAL AND ELECTRICAL CONDUCTIVITY, IN PARTICULAR FOR A SATELLITE

(71) Applicants: THALES, COURBEVOIE (FR); LUXEMBOURG INSTITUTE OF SCIENCE AND TECHNOLOGY, ESCH-SUR-ALZETTE (LU)

(72) Inventors: Martine LUTZ, FREJUS (FR); Dima TANZILLI, NICE (FR); Nicolas BURGER, MARIENTHAL (FR); Abdelghani LAACHACHI, YUTZ (FR)

(21) Appl. No.: 15/526,725

(22) PCT Filed: Nov. 13, 2015
(86) PCT No.: PCT/EP2015/076556

§ 371 Date: May 12, 2017

(30) Foreign Application Priority Data
Nov. 14, 2014 (FR) 1402561

(51) Int. Cl. C08J 5/04; B64G 1/50; F28F 21/08; H01L 31/052; H02S 40/42; C08J 5/00; H01L 23/373; F28D 15/02; F28D 21/00; B64G 1/10

(52) U.S. Cl. CPC C08J 5/042; H01L 23/3737; B64G 1/503; F28F 21/084; H01L 31/052; F28D 15/0275; H02S 40/42; C08J 5/005; B64G 1/506; B64G 1/1007; F28D 2021/0021; C08J 2300/00

(57) ABSTRACT

A composite structure comprising an organic resin and carbon fibers comprises planar structure graphene nanosheets embedded in the resin. This structure combining good properties in terms of mechanical resilience, thermal conductivity and electrical conductivity can advantageously be used for thermal dissipation devices, as solar generator substrate or else as housing of electronic components, carried on board satellites.

The field of the invention is that of composite mechanical structures which exhibit good properties in terms of mechanical resilience, thermal conductivity and electrical conductivity in particular for applications in the field of space, and which can be integrated into scientific observation and telecommunications satellites.

Generally, devices for space applications must meet increasingly severe performance levels. As regards telecommunications satellites, the latter carry on board an ever larger number of ever more complex equipment items consuming ever more energy, producing more heat.

Moreover, the future platforms of telecommunication satellites must meet increasingly severe performance requirements (precision of pointing of the antennas, mass, etc.).

Thus, telecommunications satellites must be capable of dissipating the heat produced by the on-board equipment in an efficacious manner, so as to guarantee the longevity of the latter's performance. In parallel with this, the growing multiplicity of on-board equipment items, as well as economic reasons, imposes ever severer mass constraints on the on-board components.

Telecommunications satellites usually use heat dissipators in the form of dissipative panels commonly referred to as “North-South panels” or else “North-South walls”, on account of their particular disposition on the surface of the satellites. The North-South walls are typically composed of panels and of devices for heat conduction, the latter commonly being referred to as heat pipes, and usually consist of tubular structures which are placed in a network and within which a heat-transfer fluid circulates. As regards most satellite systems produced, the structure of the North-South walls is typically made of aluminum. In the same manner, the heat pipes are typically made of aluminum. Aluminum is favored since it offers good thermal conductivity characteristics, as well as physical properties which facilitate extrusion, a method of manufacture that is particularly suitable for obtaining parts with tubular structure. Furthermore, aluminum offers known lightness characteristics.

Telecommunications satellites can also use racks, supporting the equipment and means of thermal transfer allowing the heat liberated by the equipment to be transferred to dissipative panels of North-South panel type for example. Similarly, the components making up the racks are favorably made of aluminum.

As regards scientific and observation satellites, particular missions requiring both rigid structures and panels controlled thermally by heat pipes may be envisaged, in particular for the exploration of hot planets and the sun.

In order to best meet the aforementioned constraints, and in particular the constraints related to the mass of the systems, it is envisaged to resort to structures which are alternatives to the known structures made of aluminum. It is in particular envisaged to resort to composite materials exhibiting lighter masses. In particular, composite structures based on carbon are envisaged. Indeed, recent developments allow the production of composite structures containing graphite-enriched, or “graphitized”, carbon fibers. Such fibers offer very satisfactory characteristics in terms of thermal conduction. Composite structures incorporating graphitized carbon fibers are thus envisaged, in particular to produce the structure which makes up the plane of the North-South panels of satellites, for which good thermal conductivity characteristics are sought.

According to techniques which are in themselves known from the prior art, the use of highly graphitized carbon fibers can be matched with the employment of a second carbon fiber, of “high strength” type, alleviating the insufficient mechanical resilience of the first. Typically, the first fiber, which is conducting, can be disposed substantially perpendicularly to the main axis of the heat pipes, and the second fiber, of high strength, substantially along the main axis of the heat pipes. Thus, a succession of layers comprising highly graphitized carbon fibers, embedded in a resin, and of layers comprising high-strength carbon fibers aligned substantially perpendicularly to the fibers of the neighboring layers, can be produced. It is also possible to alternate layers in which carbon fibers are disposed according to an alignment making a determined angle, for example 45°, with the fibers disposed in the neighboring layers; such a configuration, made up of a superposition of layers comprising fibers of heterogeneous nature, makes it possible to achieve composite structures whose isotropy properties are improved.

Within this framework, the Applicant has filed a patent application published under the reference 2 960 218, describing a solution based on organic resin and on carbon fibers, the resin being filled with carbon nanotubes. In order to produce a thermal dissipator, the composite material is coupled with the use of heat pipes, but nonetheless, structure current return can only be ensured imperfectly with this solution. According to this solution, the doped resin has become slightly electrically conducting, thereby already simplifying the implementation of the metallization (no scraping operation required in contradistinction to standard composites), but not enough to dispense with metallization tracks in order to ensure current return.

Therefore, the subject of the present invention is a novel composite mechanical structure with enhanced mechanical resilience and whose thermal conductivity and electrical conductivity are also improved. The originality of this structure resides in the use of graphene nanosheets as filler of the resin, of planar structure, able to exhibit larger specific surface areas than the fillers currently proposed in the solutions of the known art and in particular that based on carbon nanotubes.

The solution proposed in the present invention consists of a structure whose very good properties in terms of mechanical resilience, of very good thermal conductivity and very good electrical conductivity, thus make it possible to envisage diverse applications in structures carried on board satellites, such as thermal dissipators, housings for electronic components or else as substrate for solar generators.

More precisely, the subject of the present invention is a composite structure comprising an organic resin and carbon fibers, characterized in that it furthermore comprises planar structure graphene nanosheets embedded in said resin.

The benefit of using graphene nanosheets resides in particular in the very good thermal conductivity properties due to their large specific surface area, their sheet morphology, their large aspect ratio and their length, and in the very good properties of increased electrical conductivity with respect to that of carbon nanotubes. Indeed, the dimensions of the nanosheets of planar structure are of the order of a few tens of microns, making it possible to increase correspondingly their specific surface area with respect to those of carbon nanotubes, being able to comprise a nanotube length of the same order of magnitude but with a much smaller diameter.

According to a variant of the invention, said composite structure comprises stacks of a few graphene nanosheets of planar structure embedded in said resin.

According to a variant of the invention, the amount of filler per unit mass in terms of nanosheets in the resin lies between 5% and 20%.

The amount of filler of 20% constitutes a physical limit beyond which it is very difficult to produce an industrial “pre-preg” with a homogeneous dispersion of the nanofiller. Hence the importance of choosing a filler having good intrinsic properties, but also of dispensing with the problems of interfaces: in the present case, the morphology of the filler makes it possible to reduce the loss at the interfaces and thus to obtain at one and the same time good on-composite thermal and electrical conductivity. It should be noted that a “pre-preg” is defined as a carbon/unpolymerized filled resin composite.

According to a variant of the invention, the specific surface area of the graphene nanosheets is greater than or equal to 500 m²/g, advantageously, it may be greater than 750 m²/g.

According to a variant of the invention, the structure comprises an alternating succession of layers comprising a first plurality of carbon fibers disposed according to a determined alignment, and of layers comprising a second plurality of carbon fibers disposed according to an alignment substantially perpendicular to the alignment of said first plurality of carbon fibers.

According to a variant of the invention, the composite structure is made up of a tissue produced by a weave of a first plurality of carbon fibers disposed according to a determined alignment, and of a second plurality of carbon fibers disposed according to an alignment substantially perpendicular to the alignment of said first plurality of carbon fibers.

The subject of the invention is also a thermal dissipation device, in particular for a space application, comprising at least one dissipative panel, the dissipative panel comprising at least one skin produced in the composite structure according to the invention.

The subject of the invention is also a thermal dissipation device comprising at least one skin produced in the composite structure of the invention.

According to a variant of the invention, the skin is assembled to a network of heat pipes.

According to a variant of the invention, the dissipative panel comprises an interior skin and an exterior skin of planar shape disposed parallel to one another and fastened via structural elements.

According to a variant of the invention, the thermal dissipation device comprises an interior skin and an exterior skin of planar shape disposed parallel to one another and fastened via structural elements.

According to a variant of the invention, the structural elements are made up of a honeycomb configuration of aluminum tubes.

According to a variant of the invention, the structural elements are made up of a conducting foam.

According to a variant of the invention, the network of heat pipes is disposed externally to the dissipative panel at the surface of the interior skin.

According to a variant of the invention, the network of heat pipes is disposed internally to the dissipative panel, between the interior and exterior skins.

According to a variant of the invention, the network of heat pipes comprises one or a plurality of heat pipes of substantially tubular shape, made of aluminum.

According to a variant of the invention, the network of heat pipes comprises one or a plurality of heat pipes of substantially tubular shape, made of an aluminum alloy incorporating elements of low thermal expansion coefficient.

According to a variant of the invention, the assembling of the heat pipes to the skins is carried out by means of organic resin enriched with planar structure graphene nanosheets.

The subject of the invention is also a fixed dissipative panel for a satellite, characterized in that it is made up of at least one thermal dissipation device according to the invention.

The subject of the invention is also a deployable dissipative panel for a satellite, characterized in that it is made up of at least one thermal dissipation device according to the invention.

The subject of the invention is furthermore an electronic equipment housing, in particular for a space application, comprising electronic components positioned in a container characterized in that said container comprises the composite structure according to the invention.

Typically, the thickness of said composite structure is greater than or equal to a few millimeters, making it possible to rigidify said structure.

The subject of the invention is also a solar generator substrate characterized in that it comprises a composite structure according to the invention. Typically the thickness of said composite structure is of the order of a tenth of a millimeter, said structure being able to be flexible.

The subject of the invention is furthermore a solar panel comprising a solar generator substrate according to the invention and a set of photovoltaic cells.

The present invention will be better understood and other advantages will become apparent on reading the nonlimiting description which follows and by virtue of the appended figures among which:

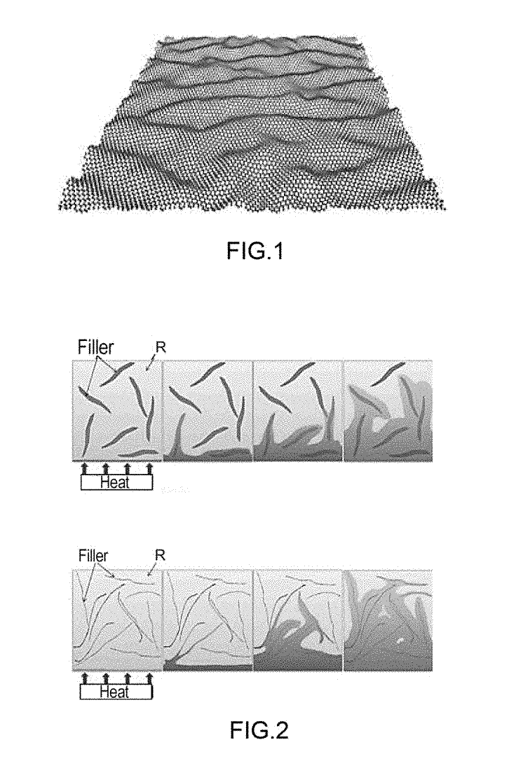

FIG. 1 illustrates a graphene nanosheet used in a composite structure according to the invention;

FIG. 2 provides a theoretical representation of the heat diffusion mechanisms in the composite samples as a function of the aspect ratio of the fillers dispersed in a resin;

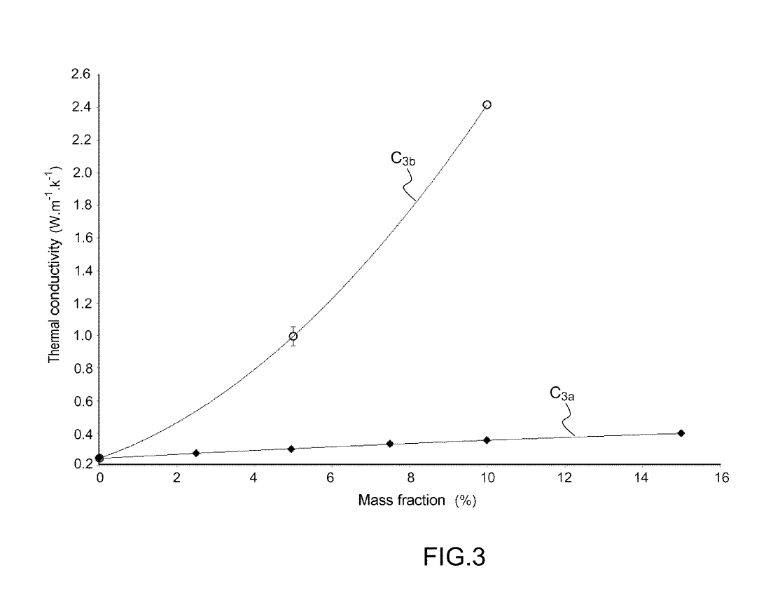

FIG. 3 illustrates the evolution of the performance in terms of thermal conductivity expressed in W/m·K as a function of the amount of filler per unit mass in the case of resin filled with carbon nanotubes and in the case of resin filled with planar structure graphene nanosheets;

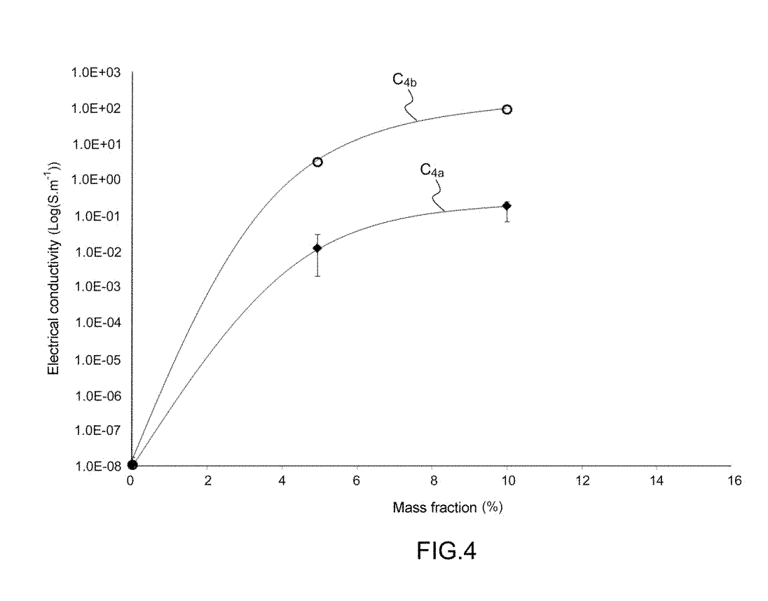

FIG. 4 illustrates the evolution of the performance in terms of electrical conductivity expressed in Log [S/m] as a function of the amount of filler per unit mass in the case of resin filled with carbon nanotubes and in the case of resin filled with planar structure graphene nanosheets;

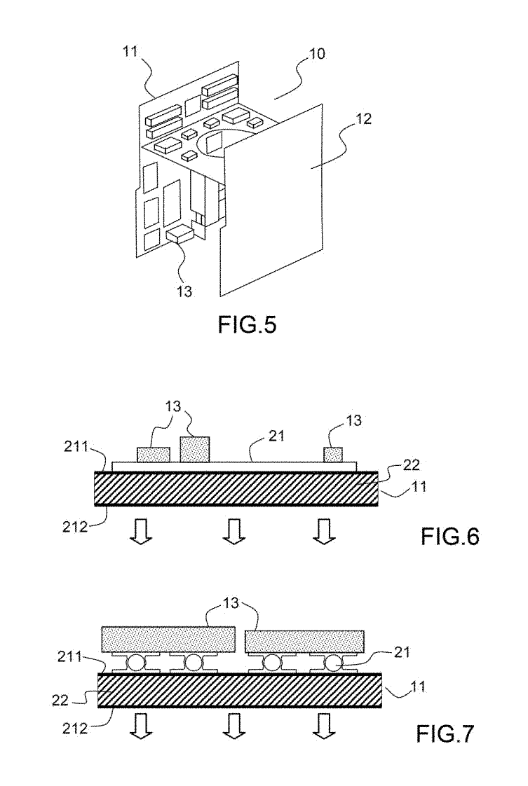

FIG. 5 illustrates a perspective view illustrating a known structure of a thermal dissipation device for a telecommunication satellite;

FIGS. 6 and 7 illustrate sectional views of a thermal dissipation device comprising a dissipative panel with the composite structure of the invention and a network of heat pipes, in a first exemplary embodiment;

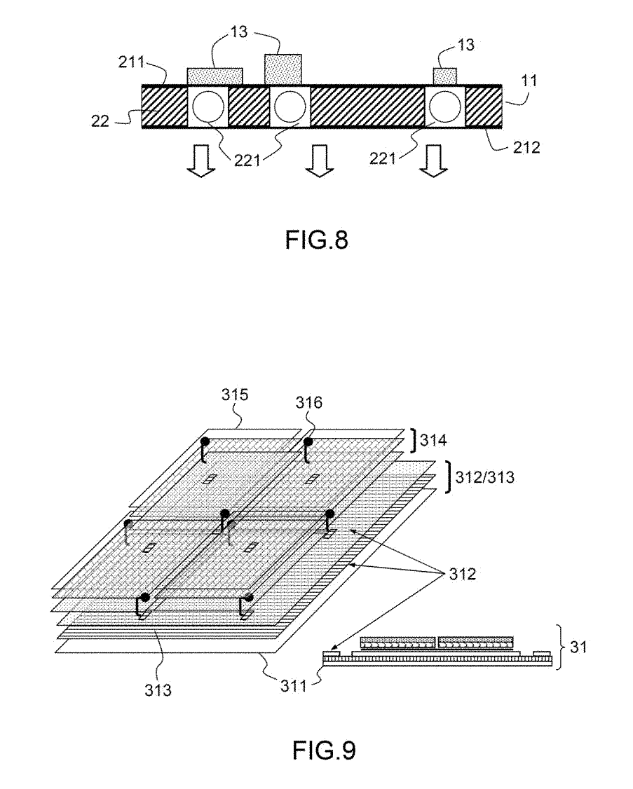

FIG. 8 illustrates a sectional view of a thermal dissipation device comprising a dissipative panel with the composite structure of the invention and a network of heat pipes, in a second exemplary embodiment;

FIG. 9 illustrates an exemplary solar panel comprising as substrate a composite structure of the invention.

Generally, the composite structure of the present invention comprises a resin filled with planar structure graphene nanosheets and carbon fibers.

In a recognized manner, a planar nanosheet of graphene is defined as being a single sheet of pure carbon, crystallized in a honeycomb structure, with a thickness of the size of a carbon atom, such as the sheet illustrated in FIG. 1. Its structure makes graphene an exceptional material, combining excellent mechanical, thermal and electrical properties. It is, however, difficult to obtain experimentally a 100% pure single graphene sheet, generally exhibiting oxygenated functions at these ends and/or a certain reagregation of the sheets leading to a form closer to graphite.

The composite structure of the present invention can thus typically comprise a stack of a few graphene nanosheets of planar structure that may typically have a thickness of between 1 nm and 10 nm and a length of more than around ten nanometers that may typically attain a length of about a few tens of microns, that may for example be of the order of 25 μm in length, with a width of the same order of magnitude, and leading for example to a specific surface area of 750 m²/g.

The Applicant has demonstrated the comparative results obtained with:
a resin filled with carbon nanofibers (referenced Carbon Nanofibers),
a resin filled with planar structure graphene nanosheets, used in the present invention (referenced Graphene).

Table 1 below summarizes the thermal conductivities obtained with 10% of filler per unit mass and as a function of their respective parameters.

| | | | | Length of | | |
|---|---|---|---|---|---|---|
| | Specific | | | the fillers | | Thermal |
| | surface | Aspect ratio | | Theo- | Ob- | conduc- |
| | area | Theo- | Ob- | retical | served | tivity |
| | (m²/g) | retical/ | served/ | (μm) | (μm) | (W/m · K) |
| Carbon | 100 | 300 | 10-20 | 30 | <1 | 0.35 |
| Nanofibers | | | | | | |
| Graphene | 750 | 2500 | 50-200 | 25 | <100 | 2.42 |

The Applicant has thus been able to show the very good results obtained in terms of thermal conductivity with a resin filled with planar structure graphene nanosheets. The increase in the specific surface area, in the aspect ratio and in the size of the fillers helps to raise performance.

The planar structure graphene nanosheet fillers possess the best combination of parameters, with a large specific surface area and a large aspect ratio, as well as a filler size that can be considered to be relatively large. The thermal conductivity of 2.42 W/m·K obtained attests thereto, resulting from a certain synergy of these parameters.

The amount of graphene filler in the composite structure also plays a role in the performance obtained. The Applicant has thus studied resins exhibiting amounts of filler per unit mass of 5% and 10% respectively.

The rise in the thermal conductivity is distinctly more marked for a resin filled with graphene at 10% than for that filled at 5%. The nanosheets are interconnected at 10% with relatively small inter-particle distances, while at 5%, the nanosheets are well dispersed and relatively isolated from one another (with a larger mean inter-particle distance). This mean inter-particle distance naturally depends on the amount of filler, as mentioned previously, but also on the aspect ratio of the filler. This postulate can in particular be illustrated by FIG. 2, which provides a theoretical representation of the heat diffusion mechanisms within a resin R comprising fillers, in the composite samples as a function of the aspect ratio of the fillers, theoretically comparing the heat diffusion in two composites having fillers with very different aspect ratios.

It is noted that the beneficial effect of the fillers with large aspect ratio on the thermal conductivity can be explained mainly by their distribution and the structural aspect of the material. Geometrically speaking, fillers with a larger aspect ratio make it possible to fill much more space in the resin, i.e. decrease the mean inter-particle distances, than in the case of fillers with a smaller aspect ratio. Thus, by decreasing these mean inter-particle distances, a certain network of interconnected nanosheets is then obtained, which thus allow much faster heat diffusion, from filler to filler.

Table 2 below illustrates the performance in terms of thermal conductivity and the electrical conductivity, in the case of unfilled resin, in the case of resin filled with an amount of filler of 5% of planar structure graphene nanosheets and with an amount of filler of 10% of planar structure graphene nanosheets.

TABLE 2

| | Electrical | | Thermal |
|---|---|---|---|
| | conductivity | | conductivity |
| | (S/m) | | (W/mK) |
| Unfilled resin | 1.49 | 10⁻⁸ | 0.23 |
| Resin filled to 5% | 3.24 | | 1 |
| Resin filled to 10% | 9.30 | 10 ⁺¹ | 2.42 |

The associated curves represented in FIGS. 3 and 4 moreover illustrate the evolution of the performance that may be expected respectively in terms of thermal conductivity expressed in W/m·K and in terms of electrical conductivity expressed in Log [S/m] as a function of the amount of filler per unit mass in the case of resin filled with carbon nanotubes and in the case of resins filled with planar structure graphene nanosheets. It emerges very clearly from all of the two curves C₃ₐ and C₄ₐ (resin filled with nanotubes) and of the curves C_{3b} and C_{4b} (resin filled with graphene nanosheets) that the performance is better with the resin, used in the present invention, filled with planar structure graphene nanosheets. The evolution of the curves of electrical conductivity demonstrates the attaining of an asymptote onward of an amount of filler per unit mass of about 8 to 10%.

Exemplary Structure for a Thermal Dissipator Application Intended in Particular to be Able to be Carried on Board a Satellite

To produce a skin with strong thermal dissipation property, planar structure graphene nanosheets are mixed with resin intended for the composite structure.

The filled resin is filmed so as to be able to produce a pre-preg based on carbon reinforcement (carbon tissue consisting of long fibers of high-modulus carbon, typically fiber modulus greater than 400 GPa).

This pre-preg is then draped (stack of quasi-isotropic layers) and then polymerized in the form of skins. The polymerization can be carried out under pressure and temperature, the operation can typically be conducted in a press or in an autoclave. It is thus possible to produce composite structures according to the invention that may exhibit variable thicknesses, according to the stack of layers of pre-preg before the operation of polymerization and of hardening of said composite structure that may in particular be intended for thermal dissipator applications.

For this purpose, FIG. 5 presents a perspective view illustrating a known structure of a thermal dissipation device for a telecommunication satellite.

Typically, a communication satellite comprises in particular a communication module 10. The communication module 10 comprises a plurality of strongly dissipative items of electronic equipment 13. The items of electronic equipment 13 are installed on networks of heat pipes, which are not represented in the present figure but are described in detail below with reference to FIGS. 2a, 2b and 3. The items of electronic equipment 13 are disposed inside the communication satellite. The heat pipes are disposed on the internal surface of dissipative panels 11, 12, or else inside the dissipative panels 11,12. The networks of heat pipes allow transport and distribution of the thermal power over the total surface area of the dissipative panels 11, 12. The exterior surface of the dissipative panels 11, 12 then radiate this power to the surrounding space. For better radiation of the thermal power, the exterior surfaces of the dissipative panels 11, 12 are for example covered with optical solar reflectors, commonly referred to by the abbreviation OSR. The structure of the North-South panels is described in detail below with reference to FIGS. 6, 7 and 8.

FIGS. 6 and 7 present sectional views illustrating the structure of a thermal dissipation device comprising a dissipative panel and a network of heat pipes, in a first exemplary embodiment.

In the first exemplary embodiment, a network of heat pipes comprising at least one heat pipe 21 can be disposed inside a dissipative panel 11. The interior and exterior surfaces of the North-South panel 11 can be made up of two surface structures or “skins”, respectively an interior skin 211 and an exterior skin 212, defining substantially mutually parallel planes. The skins 211, 212 can be fastened via structural elements 22. The structural elements 22 can for example, typically, form a so-called “honeycomb” structure. The items of electronic equipment 13 are disposed on the network of heat pipes 21.

In the example illustrated by FIG. 6, a heat pipe of essentially tubular shape is represented in a transverse cross section.

In the example illustrated by FIG. 7, several portions of one and the same heat pipe, or else of several heat pipes, are represented in a transverse cross-sectional view. A heat-transfer fluid circulates in the heat pipes 21. Typically in applications of telecommunication satellite type, the heat-transfer fluid used is ammonia.

In typical structures known from the prior art, the heat pipes 21, as well as the skins 211, 212 and the structural elements making up the dissipative panels 11, can consist of aluminum.

FIG. 8 is a schematic representation of the composition of a dissipative panel according to a variant embodiment.

FIG. 8 presents a dissipative panel structure 11 in itself known from the prior art, within which are integrated the networks of heat pipes 21, appearing in a transverse cross section in the figure. In such a structure, the items of electronic equipment 13 can be disposed directly on a skin 211, 212, substantially above the networks of heat pipes 21, the networks of heat pipes 21 being disposed between the two skins 211, 212 of the dissipative panel 11. In a similar manner to the structures described hereinabove with reference to FIGS. 6 and 7, structural elements 22 making up for example a honeycomb structure can fasten the assembly.

According to the present invention, it becomes possible moreover to make structure current since the filler made of graphene nanosheets also makes it possible to have good electrical conductivity in addition to good thermal conductivity, without having to resort for example to employing metallization tracks at the surface of the panels so as to recover the current, the structure of the present invention being a sufficiently good electrical conductor to obtain this structure current return directly.

Exemplary Structure for a Solar Panel Application Intended in Particular to be Able to be Carried on Board a Satellite

The composite structure of the invention can also advantageously serve as substrates of solar panels. It is indeed possible to produce very thin films, exhibiting great flexibility because of their small thickness (which may typically be of the order of a few tenths of a mm) and which may thus in a variant be wound so that they may be deployed. FIG. 9 illustrates for this purpose an exemplary solar panel 31 comprising the following stack:
a substrate 311 corresponding to the composite structure of the invention;
a set of insulating layers 312 between which an electrical network 313 is produced;
at the stack surface 312/313 corresponding to an electrical shroud, a set of photovoltaic cells 314:
an anti-radiation glass shroud 315;
electrical connections 316.

It should be noted that, according to another variant of the invention, the solar panel can also be a rigid solar panel.

Exemplary Structure for an Electronic Housing Intended in Particular to be Able to be Carried on Board a Satellite

The composite structure of the invention can also be designed to exhibit a sufficient thickness, typically of a few millimeters, and be shaped to serve as electronic housing for electronic components for example, making it possible to constitute an alternative to the metallic alloys used in the on-board electronic equipment packaging, in particular in satellites.

Such parts can be produced by molding or injection with appropriate molds on the basis of the pre-pregs described previously, so as to be shaped, the resin being polymerized so as to harden in the final phase.

1. A composite structure comprising an organic resin and carbon fibers, comprising planar structure graphene nanosheets embedded in said resin.

2. The composite structure as claimed in claim 1, comprising stacks of a few graphene nanosheets of planar structure embedded in said resin.

3. The composite structure as claimed in claim 1, wherein the amount of filler per unit mass in terms of nanosheets in the resin lies between 5% and 20%.

4. The composite structure as claimed in claim 1, wherein the specific surface area of the graphene nanosheets is greater than or equal to 500 m²/g.

5. The composite structure as claimed in claim 1, comprising an alternating succession of layers comprising a first plurality of carbon fibers disposed according to a determined alignment, and of layers comprising a second plurality of carbon fibers disposed according to an alignment substantially perpendicular to the alignment of said first plurality of carbon fibers.

6. The composite structure as claimed in claim 1, wherein the composite structure is made up of a tissue produced by a weave of a first plurality of carbon fibers disposed according to a determined alignment, and of a second plurality of carbon fibers disposed according to an alignment substantially perpendicular to the alignment of said first plurality of carbon fibers.

7. A thermal dissipation device, in particular for a space application, comprising at least one dissipative panel, the dissipative panel comprising at least one skin produced in the composite structure as claimed in claim 1.

8. The thermal dissipation device as claimed in claim 7, wherein the skin is assembled to a network of heat pipes.

9. The thermal dissipation device as claimed in claim 7, wherein the dissipative panel comprises an interior skin and an exterior skin of planar shape disposed parallel to one another and fastened via structural elements.

10. The thermal dissipation device as claimed in claim 9, wherein the structural elements are made up of a honeycomb configuration of aluminum tubes.

11. The thermal dissipation device as claimed in claim 9, wherein the structural elements are made up of a conducting foam.

12. The thermal dissipation device as claimed in claim 8, wherein the network of heat pipes is disposed externally to the dissipative panel, at the surface of the interior skin.

13. The thermal dissipation device as claimed in claim 8, wherein the network of heat pipes is disposed internally to the dissipative panel, between the interior skin and the exterior skin.

14. The thermal dissipation device as claimed in claim 8, wherein the network of heat pipes comprises one or a plurality of heat pipes of substantially tubular shape, made of aluminum.

15. The thermal dissipation device as claimed in claim 8, wherein the network of heat pipes comprises one or a plurality of heat pipes of substantially tubular shape, made of an aluminum alloy incorporating elements of low thermal expansion coefficient.

16. The thermal dissipation device as claimed in claim 8, wherein the assembling of the heat pipes to the skins is carried out by means of organic resin enriched with graphene nanosheets of planar structure.

17. An electronic equipment housing, in particular for a space application, comprising electronic components positioned in a container wherein said container comprises the composite structure as claimed in claim 1.

18. The electronic equipment housing as claimed in claim 17, wherein the thickness of said composite structure is greater than or equal to a few millimeters.

19. A solar generator substrate comprising a composite structure as claimed in claim 1.

20. The solar generator substrate as claimed in claim 19, wherein the thickness of said composite structure is of the order of a tenth of a millimeter, said structure being flexible.

21. A solar panel comprising a solar generator substrate as claimed in claim 19 and a set of photovoltaic cells.
